(19) United States
(12) Patent Application Publication
(10) Pub. No.: US 2010/0226166 A1
(43) Pub. Date: Sep. 9, 2010

(54) MOS capacitor and charge pump with MOS capacitor

(76) Inventors: Sang-Hee Jung, Yongin-si (KR); Young-Kwan Kim, Dongnae-gu (KR)

Correspondence Address: LAW OFFICE OF MONICA H CHOI, P O BOX 3424, DUBLIN, OH, 430160204, US

(21) Appl. No.: 12/454,121

(22) Filed: May 13, 2009

(30) Foreign Application Priority Data
Mar. 3, 2009 (KR) 10-2009-0018110

(51) Int. Cl. G11C 11/24; G11C 5/14; G05F 1/10; H01L 29/94

(52) U.S. Cl. 365/149; 365/226; 327/536; 257/299; 257/E29.345

(57) ABSTRACT

A MOS capacitor in a charge pump includes a MOS device with at least one body bias region and a device body of a same conductivity type for providing maximum capacitance over a wide voltage range. The MOS capacitor also includes a gate forming a first terminal of the MOS capacitor, and the at least one body bias region forms a second terminal of the MOS capacitor. The MOS capacitor further includes a multiple-well structure formed with the device body and a deep well in a substrate for enhanced noise immunity.

### CROSS-REFERENCE TO RELATED APPLICATION(S)

The present application claims priority under 35 U.S.C. § 119 to Korean Patent Application No. 10-2009-0018110, filed on Mar. 3, 2009, which is incorporated herein by reference in its entirety.

### TECHNICAL FIELD

The present invention relates generally to MOS (metal oxide semiconductor) capacitors and charge pumps, and more particularly, to a charge pump having a MOS capacitor with a multiple-well structure for providing voltage in a semiconductor device such as a memory device for example.

### BACKGROUND OF THE INVENTION

A charge pump is commonly used in a semiconductor device such as a memory device for providing a voltage with high magnitude above that provided by a power source. For example, a memory device such as a DRAM (dynamic random access memory) device, a EEPROM (electrically erasable and programmable read only memory) device, or a flash memory device commonly has charge pumps for providing voltages used to write, read, and/or erase data.

FIG. 1 shows a common charge pump 100 of the prior art with a capacitor C and a voltage supplier 102 providing a driving voltage VN1 at a first node N1. The capacitor C is coupled between the first node N1 and a second node N2.

In a first time period, the first node N1 is biased at a low supply voltage VSS, and the second node N2 is biased at a high supply voltage VDD. Thereafter during a second time period, when the first node N1 is biased at the high supply voltage VDD, a positive boosted voltage VPP that is 2*VDD is generated at the second node N2.

FIG. 2 shows operation of the charge pump 100 for generating a negative voltage. In that case during the first time period, the first node N1 is biased at the high supply voltage VDD, and the second node N2 is biased at the low supply voltage VSS. Thereafter during the second time period, when the first node N1 is biased at the low supply voltage VSS, a negative boosted voltage VBB that is −VDD is generated at the second node N2.

In the prior art, the capacitor C in the charge pump of FIG. 2 is implemented using a PMOSFET (P-channel Metal Oxide Semiconductor Field Effect Transistor) 110 as illustrated in FIG. 3. The PMOSFET 110 includes an N-well 112 formed in a P-substrate 114, and includes a drain 116 and a source 118 formed in the N-well 112. In addition, a gate dielectric 120 and a gate electrode 122 are formed over a channel region of the N-well between the drain 116 and the source 118.

Referring to FIGS. 2 and 3, the drain 116 and the source 118 form the first node N1 of the capacitor C in the charge pump 100, and the gate electrode 122 forms the second node N2 of the capacitor C in the charge pump 100.

The capacitor C implemented with the PMOSFET 110 is disadvantageous because the capacitance of the capacitor C is decreased near the threshold voltage of the PMOSFET 110. In addition, external noise may cause the P-N junction formed by the N-well 112 and the P-substrate 114 to turn on resulting in malfunction of the charge pump 100.

Accordingly, a charge pump with a capacitor having stable capacitance and operation is desired.

### SUMMARY OF THE INVENTION

Accordingly, a MOS (metal oxide semiconductor) capacitor is formed with a multiple-well structure for providing stable capacitance in a charge pump for enhanced performance.

In a general aspect of the present invention, a MOS capacitor includes a MOS device with at least one body bias region and a device body of a same first conductivity type. The MOS capacitor also includes a gate forming a first terminal of the MOS capacitor, and the at least one body bias region forms a second terminal of the MOS capacitor. The MOS capacitor further includes a multiple-well structure formed with the device body and a deep well in a substrate.

In an example embodiment of the present invention, the substrate abuts the deep well. In a further embodiment of the present invention, the MOS capacitor also includes at least one side well formed to abut the deep well, and the side well and the deep well abut the device body. The MOS capacitor further includes at least one well bias region formed in the side well. In another embodiment of the present invention, multiple body bias regions are formed to sides of the gate in the device body.

In an example embodiment of the present invention, the multiple body bias regions and the device body are of the first conductivity type. In addition, the at least one well bias region, the side well, and the deep well are of a second conductivity type that is opposite of the first conductivity type.

In another embodiment of the present invention, the multiple body bias regions have a higher dopant concentration than the device body. Furthermore, the at least one well bias region has a higher dopant concentration than the side well and the deep well.

In a further embodiment of the present invention, the side well, the deep well, and the substrate are biased such that the substrate forms a reverse biased PN diode with the side well and the deep well.

In another embodiment of the present invention, the MOS capacitor includes at least three body bias regions formed in the device body, and the body bias regions are coupled together to form the second terminal of the MOS capacitor. In addition, the MOS capacitor includes a plurality of gates, each formed over a respective portion of the device body between a respective pair of the body bias regions. The gates are coupled together to form the first terminal of the MOS capacitor.

In another aspect of the present invention, a MOS (metal oxide semiconductor) capacitor includes a depletion-type MOS device including a device body, at least one body bias region, and a gate forming a first terminal of the MOS capacitor. The at least one body bias region forms a second terminal of the MOS capacitor. The MOS capacitor also includes a multiple-well structure formed with the device body and a deep well in a substrate.

Such MOS capacitors are advantageously used in a charge pump including a bias source for alternately applying a voltage to at least one of the first and second terminals of the MOS capacitor for generating a pumped voltage at one of the first and second terminals of the MOS capacitor.

In one example embodiment of the present invention, the at least one body bias region is doped to have a P+ conductivity, the device body is doped to have P conductivity, the deep well and the side well are doped to have N conductivity, and the substrate is doped to have P conductivity, when the pumped voltage is a negative voltage. Alternatively, the at least one body bias region is doped to have a N+ conductivity, the device body is doped to have N conductivity, the side well and the deep well are doped to have P conductivity, and the substrate is doped to have N conductivity, when the pumped voltage is a positive voltage.

Such a charge pump may advantageously be used as a voltage source in a memory device having a memory cell array. In that case, the charge pump generates a pumped voltage used during operation of the memory cell array. For example, an electronic system includes an input device, an output device, such a memory device, and a processor device coupled to the input device, the output device, and the memory device.

In this manner, the MOS device forms a capacitor with stable capacitance over a large operating voltage range. In addition, with the multiple-well structure forming multiple reversed biased P-N junctions, the MOS device capacitor is more immune to noise. Furthermore, because many body bias regions and gates may be formed in the shared continuous device body, the MOS capacitor may be formed to have high capacitance with small area.

These and other features and advantages of the present invention will be better understood by considering the following detailed description of the invention which is presented with the attached drawings.

### BRIEF DESCRIPTION OF THE DRAWINGS

FIG. 1 shows a circuit diagram of a charge pump for generating a positive pumped voltage, according to the prior art;

FIG. 2 shows a circuit diagram of a charge pump for generating a negative pumped voltage, according to the prior art;

FIG. 3 shows a cross-sectional view of a PMOSFET (P-channel metal oxide semiconductor field effect transistor) for implementing a capacitor in the charge pump of FIG. 2, according to the prior art;

FIG. 4 shows a charge pump with a cross-sectional view of a MOS device having a multiple-well structure for forming a capacitor of the charge pump, according to an embodiment of the present invention;

FIG. 5 shows a top view of a gate of the MOS device of FIG. 4, according to an embodiment of the present invention;

FIG. 6 shows a plot of capacitance versus bias voltage for the MOS device of FIG. 4, according to an embodiment of the present invention;

FIG. 7 illustrates multiple reverse biased P-N junctions formed in the multiple-well structure of FIG. 4, according to an embodiment of the present invention;

FIGS. 8, 9, and 10 illustrate cross-sectional views during fabrication of the multiple-well structure of FIG. 4, according to an embodiment of the present invention;

FIG. 11 shows a partial circuit diagram of the charge pump of FIG. 4, according to an embodiment of the present invention;

FIGS. 12A, 12B, and 12C show various voltages generated at nodes of the charge pump of FIG. 11, according to an embodiment of the present invention;

FIG. 13 shows multiple gates formed on a continuous device body of the MOS device for increasing capacitance, according to an embodiment of the present invention;

FIG. 14 shows a top view of the MOS device of FIG. 13 with multiple gates, according to an embodiment of the present invention;

FIG. 15 shows a circuit diagram of a charge pump having the MOS device of FIG. 13 with multiple gates, according to an embodiment of the present invention;

FIG. 16 shows a block diagram of a memory device including any of the charge pumps of embodiments of the present invention;

FIG. 17 shows the memory device of FIG. 16 formed as part of an integrated circuit die on a semiconductor wafer, according to an embodiment of the present invention;

FIG. 18 shows a block diagram of an electronic system having the memory device of FIG. 16, according to an embodiment of the present invention; and

FIG. 19 shows a cross-sectional view of an alternative MOS device with a multiple-well structure for forming a capacitor, with different conductivities from the MOS device of FIG. 4 according to an alternative embodiment of the present invention.

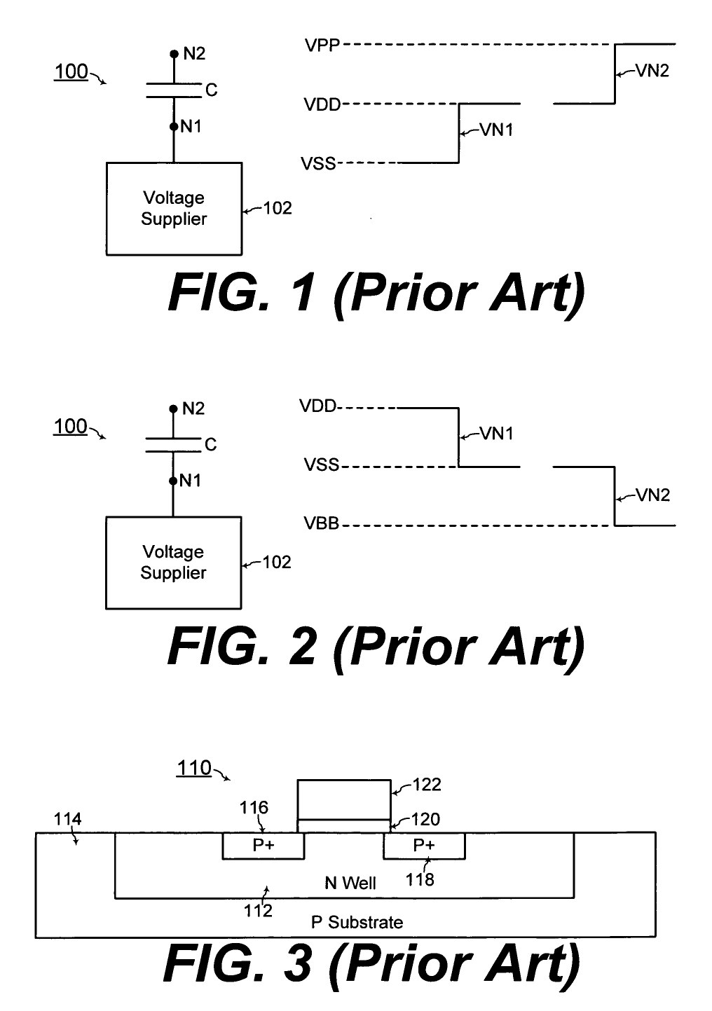

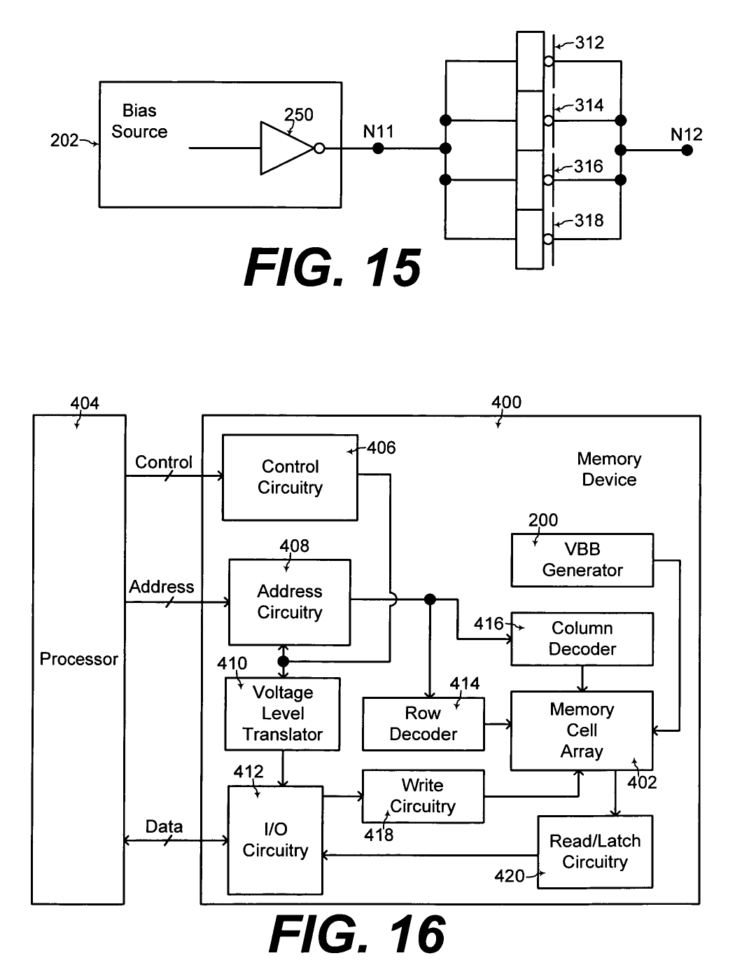

The figures referred to herein are drawn for clarity of illustration and are not necessarily drawn to scale. Elements having the same reference number in FIGS. 1, 2, 3, 4, 5, 6, 7, 8, 9, 10, 11, 12A, 12B, 12C, 13, 14, 15, 16, 17, 18, and 19 refer to elements having similar structure and/or function, unless stated other-wise.

### DETAILED DESCRIPTION

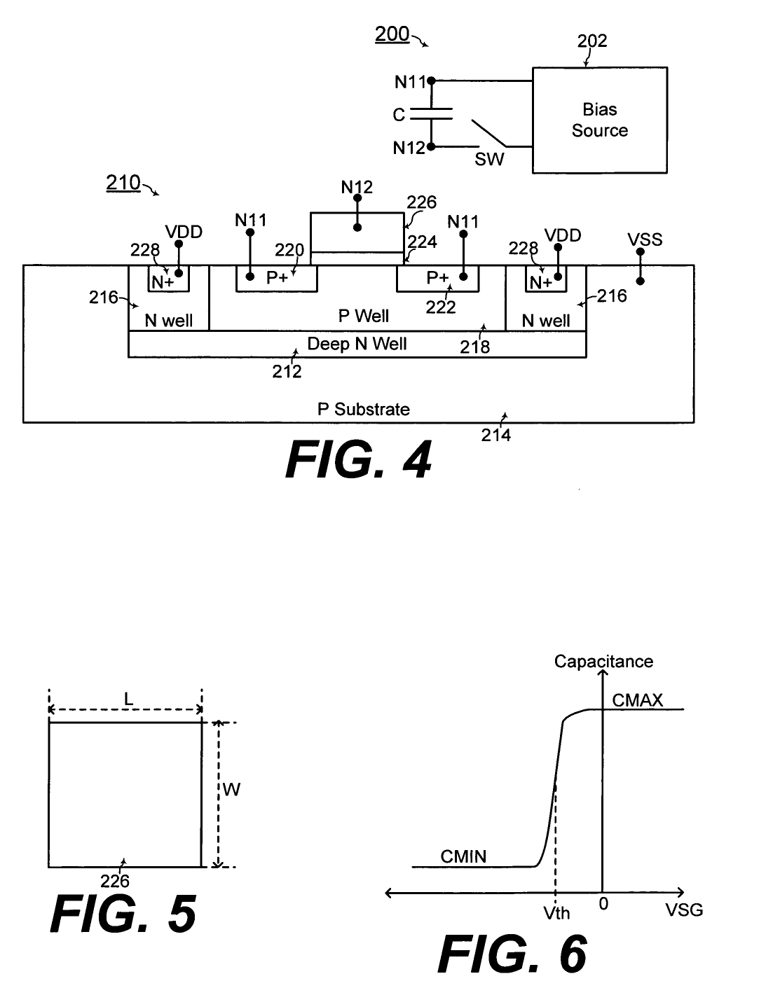

FIG. 4 shows a block diagram of a charge pump 200 with a cross-sectional view of a MOS (metal oxide semiconductor) device 210 having a multiple-well structure for forming a capacitor C of the charge pump 200, according to an embodiment of the present invention. The charge pump 200 further includes a bias source 202 coupled to a first node N11 of the capacitor C and coupled to a second node N12 of the capacitor C via a switch SW.

Further referring to FIG. 4, the MOS device 210 includes a deep well 212 formed in a semiconductor substrate 214. The MOS device 210 further includes at least one side well 216 formed to abut the deep well 212. The MOS device 210 also includes a P well 218 forming a device body of the MOS device 210.

Also in FIG. 4, the MOS device 210 includes a first body bias region 220 and a second body bias region 222 formed in the P well 218 for providing low resistance contact and biasing of the P well 218. A gate dielectric 224 is formed over a channel portion of the P well disposed between the body bias regions 220 and 222. A gate 226 is formed over the gate dielectric 224. The gate dielectric 224 is comprised of an insulating material, and the gate 226 is comprised of a conductive material.

Additionally in FIG. 4, the MOS device 210 includes a well bias region 228 formed in the side well 216 for providing low resistance contact and biasing of the side well 216 and the deep well 212. In one example embodiment of the present invention, the deep well 212, the side well 216, and the well bias region 228 are doped to have N type conductivity. The P well forming the device body 218, the body bias regions 220 and 222, and the substrate 214 are doped to have P type conductivity.

In addition, the body bias regions 220 and 222 have a respective P type dopant concentration that is at least fifteen times higher than a respective P type dopant concentration of the P well 218. Furthermore, the well bias region 228 has a respective N type dopant concentration that is at least fifteen times higher than a respective N type dopant concentration of the side well 216 and the deep well 212. Also in FIG. 4, the body bias regions 220 and 222 form the first node N11 of the capacitor C, and the gate 226 forms the second node N12 of the capacitor C.

FIG. 5 shows a top view of the gate 226 having a width W and a length L. FIG. 6 shows a plot of capacitance versus a bias voltage VSG across at least one of the body bias regions 220 and 222 and the gate 226. In that case when such a bias voltage VSG is above a threshold voltage Vth of the MOS device 210, the capacitance of the capacitor C is maintained at a maximum capacitance CMAX expressed as:

∈₀*(W*L)/D

Above, ∈₀ is the permittivity of the gate dielectric 224, W is the width of the gate 226, L is the length of the gate 226, and D is the thickness of the gate dielectric 224.

Referring to FIG. 6, note that the capacitance of the capacitor C decreases when the bias voltage VSG is less than the threshold voltage Vth of the MOS device 210 during high frequency operation of the charge pump 200. In one embodiment of the present invention, the threshold voltage Vth of the MOS device 210 is negative such that the capacitance of the capacitor C is maintained at the maximum capacitance CMAX for a wider range of the bias voltage VSG. Generally, the MOS device 210 having the threshold voltage Vth that is negative is referred to as a depletion-type MOS device.

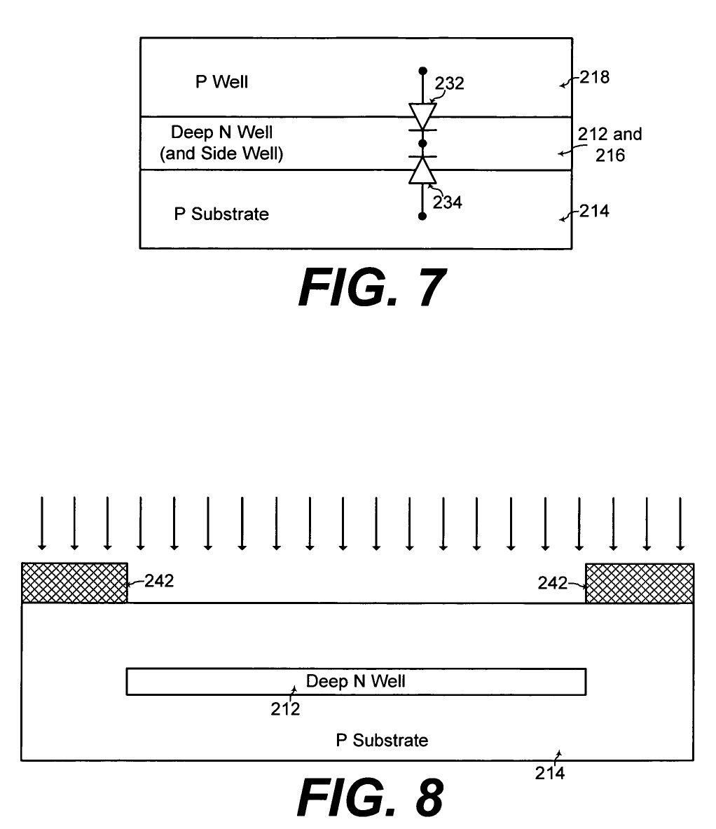

Referring to FIGS. 4 and 7, a first diode 232 is formed from a first P-N junction between the P well 218 (that is of P type conductivity) and the deep well 212 and the side well 216 (that are of N type conductivity). In addition, a second diode 234 is formed from a second P-N junction between the substrate 214 (that is of P type conductivity) and the side well 216 and the deep well 212 (that are of N type conductivity).

The P well 218, the deep well 212 (with the side well 216), and the substrate 214 form a multiple-well structure of the MOS device 210. The multiple-well structure of the MOS device 210 includes at least two P-N junctions formed from the substrate 214. The deep well 212 and the side well 216 surround the P well 218 forming the device body of the MOS device 210. The deep well 212 and the side well 216 abut the substrate 214.

Further referring to FIGS. 4 and 7, the P type substrate 214 is biased at a low power voltage VSS. In addition, the side well 216 and the deep well 212 are biased at a high power voltage VDD. Thus, the second diode 234 is reversed biased to be maintained off for further electrically isolating the P well 218. Such electrical isolation enhances noise immunity of the MOS device 210.

FIGS. 8, 9, and 10 illustrate cross-sectional views during fabrication of the multiple-well structure of FIG. 4, according to an embodiment of the present invention. Referring to FIG. 8, an ion implantation is performed with an N type dopant for forming the deep N well 212 in the P type substrate 214. A first ion implantation mask 242 is patterned over the substrate 214 before such an ion implantation. The N type dopant is implanted deep into the exposed region of substrate 214 to form the deep N well 212 below the surface of the substrate 214.

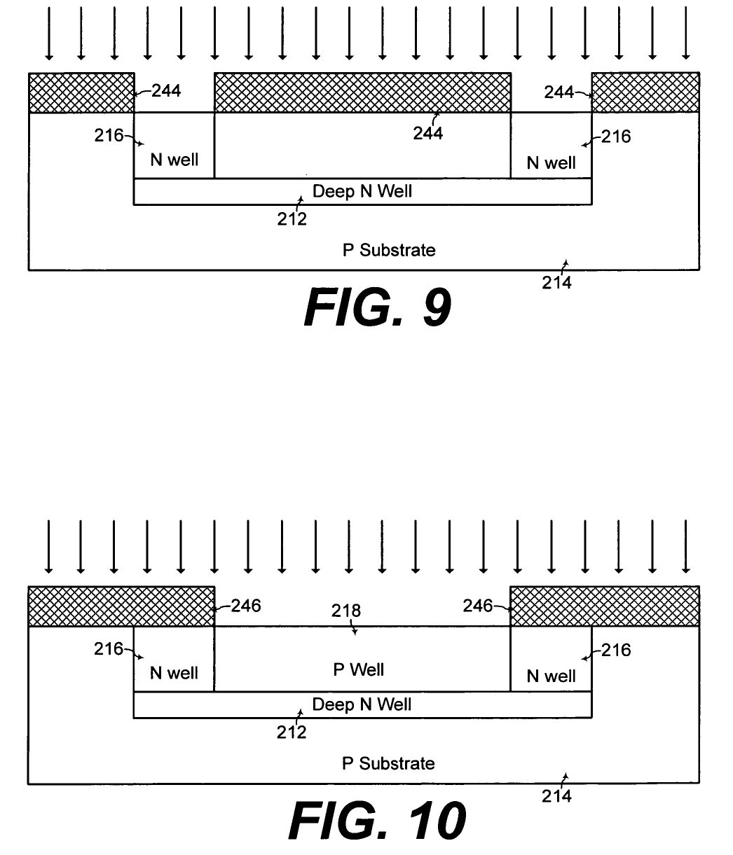

Thereafter referring to FIG. 9, another ion implantation is performed with an N type dopant for forming the side well 216 in the P type substrate 214. A second ion implantation mask 244 is patterned over the substrate 214 before such an ion implantation. The N type dopant is implanted into the exposed regions of substrate 214 to form the side well 216 to abut the deep well 212. Alternatively, the bottom of the side well 216 may be formed to enter into the deep well 212. In any case, the side well 216 and the deep well 212 form a continuous region of N type conductivity that surrounds the P well 218 that is of P type conductivity.

In an example embodiment of the present invention in FIG. 10, a further ion implantation is performed with a P type dopant for forming the P well 218 that is the device body of the MOS device 210. A third ion implantation mask 246 is patterned over the substrate 214 before such an ion implantation. The P type dopant is implanted into the exposed region of substrate 214 to form the P well 218 and may determine the threshold voltage of the MOS device 210. Thereafter referring to FIGS. 10 and 4, the other structures of the MOS device 210 such as the gate dielectric 224, the gate 226, the body bias regions 220 and 222, and the well bias region 228 are formed.

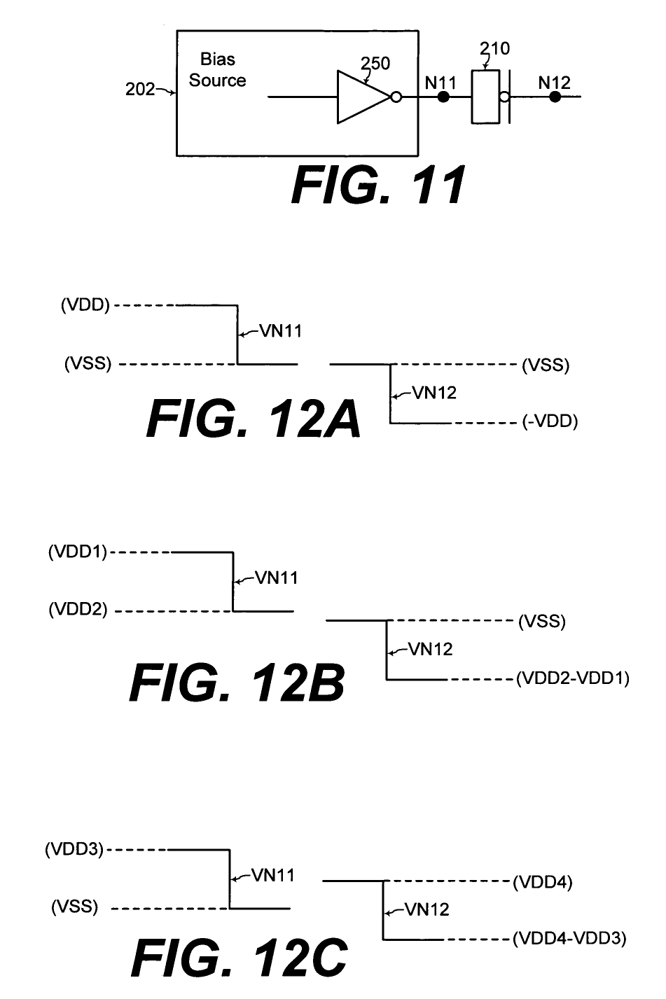

FIG. 11 shows a partial circuit diagram of the charge pump 200 of FIG. 4, according to an embodiment of the present invention. The bias source 202 includes an inverter 250 providing a respective voltage VN11 applied at the first node N11 of the MOS device 210 forming the capacitor C. FIGS. 12A, 12B, and 12C show various voltages VN11 generated at the first node N11 of MOS device 210 and various voltages VN12 generated at the second node N12 of the MOS device 210 according to example embodiments of the present invention.

Referring to FIG. 12A, during a first time period, the high power voltage VDD is the voltage VN11 generated at the first node N11, and the low power voltage VSS (which may be a ground voltage for example) is the voltage VN12 generated at the second node N12. Such voltages VN11 and VN12 during the first time period may be generated from the bias source 202 with the switch SW being closed.

During a second time period after the first time period, the voltage VN11 at the first node N11 has transitioned to the low power voltage VSS, and the switch SW is opened. In that case during the second time period after the first time period, the voltage VN12 that is the negative of the high power voltage VDD (i.e., −VDD) is generated at the second node N12.

Referring to FIG. 12B, during a first time period, a first power voltage VDD1 is the voltage VN11 generated at the first node N11, and the low power voltage VSS (which may be a ground voltage for example) is the voltage VN12 generated at the second node N12. Such voltages VN11 and VN12 during the first time period may be generated from the bias source 202 with the switch SW being closed.

During a second time period after the first time period, the voltage VN11 at the first node N11 has transitioned to a second power voltage VDD2 from the first power voltage VDD1, and the switch SW is opened. In that case during the second time period after the first time period in FIG. 12B, the voltage VN12 that is a difference between the second and first power voltages VDD2 and VDD1 (i.e., VDD2−VDD1) is generated at the second node N12. In the example of FIG. 12B, the second power voltage VDD2 is higher than the low power voltage VSS (which may be a ground voltage for example).

Referring to FIG. 12C, during a first time period, a third power voltage VDD3 is the voltage VN11 applied at the first node N11, and a fourth power voltage VDD4 is the voltage VN12 applied at the second node N12. Such voltages VN11 and VN12 during the first time period may be generated from the bias source 202 with the switch SW being closed.

During a second time period after the first time period, the voltage VN11 at the first node N11 has transitioned to the low power voltage VSS (which may be a ground voltage for example), and the switch SW is opened. In that case during the second time period after the first time period in FIG. 12C, the voltage VN12 that is a difference between the fourth and third power voltages VDD4 and VDD3 (i.e., VDD4−VDD3) is generated at the second node N12. In the example of FIG. 12C, the fourth power voltage VDD4 is higher than the low power voltage VSS (which may be a ground voltage for example).

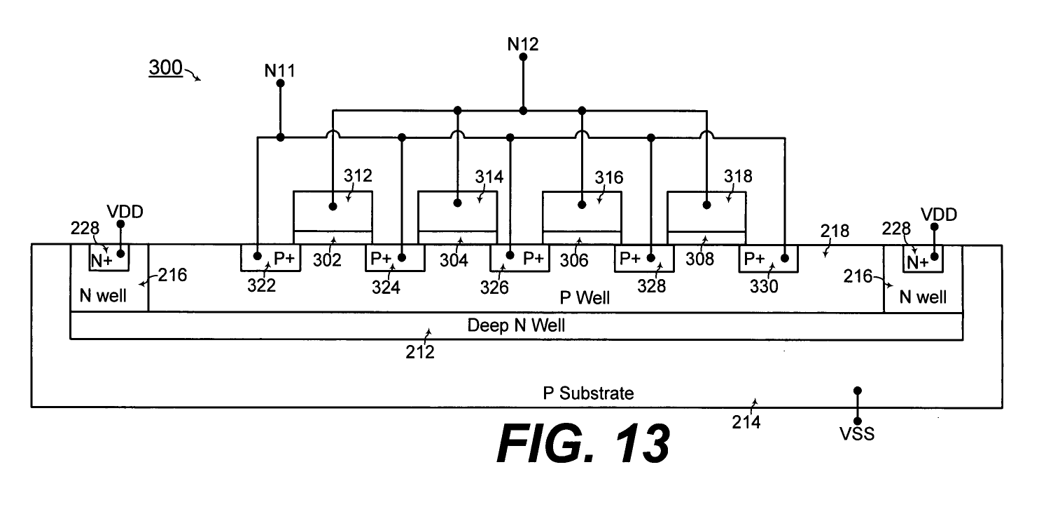

FIG. 13 shows a cross-sectional view of a MOS device 300 according to an alternative embodiment of the present invention. Elements having the same reference number in FIGS. 4 and 13 refer to elements having similar structure and/or function. Thus, the MOS device 300 also includes the multiple-well structure of the P well 218, the deep well 212 with the side well 216, and the substrate 214. However in FIG. 13, multiple gates 312, 314, 316, and 318 are formed over the continuous device body 218 for increasing the capacitance provided by the MOS device 300.

The MOS device 300 includes a first gate dielectric 302, a second gate dielectric 304, a third gate dielectric 306, and a fourth gate dielectric 308. In addition, the MOS device 300 also includes a first gate 312, a second gate 314, a third gate 316, and a fourth gate 318 formed over the gate dielectrics 302, 304, 306, and 308, respectively.

A first body bias region 322 is formed to a side of the first gate 312 in the P well 218. A second body bias region 324 is formed between the first and second gates 312 and 314 in the P well 218. A third body bias region 326 is formed between the second and third gates 314 and 316 in the P well 218. A fourth body bias region 328 is formed between the third and fourth gates 316 and 318 in the P well 218. A fifth body bias region 330 is formed to a side of the fourth gate 318 in the P well 218.

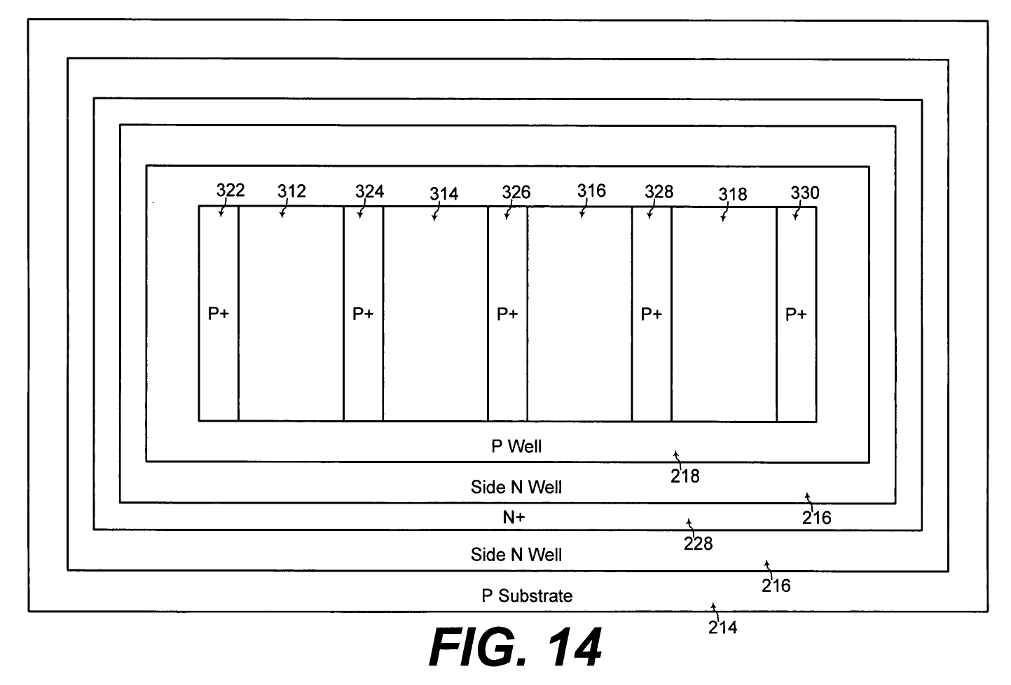

In this manner, each of the gates 312, 314, 316, and 318 is formed over a respective portion of the device body 218 between a respective pair of the body bias regions 322, 324, 326, 328, and 330. FIG. 14 shows a top view (i.e., a lay-out view) of the MOS device 300 of FIG. 13 including the body bias regions 322, 324, 326, 328, and 330 formed to the sides of the gates 312, 314, 316, and 318 in the P well 218. The body bias regions 322, 324, 326, 328, and 330 have a respective P type dopant concentration that is at least fifteen times higher than a respective P type dopant concentration of the P well 218.

Furthermore in FIG. 13, the body bias regions 322, 324, 326, 328, and 330 are connected together to form the first node N11 of the capacitor C, and the gates 312, 314, 316, and 318 are connected together to form the second node N12 of the capacitor C, as illustrated in the circuit diagram of FIG. 16. If each of the gates 312, 314, 316, and 318 has a width of W and a length of L, the total capacitance of the MOS device 300 is as follows:

4*∈₀*(W*L)/D

Above, ∈₀ is the permittivity and D is the thickness of the gate dielectrics 302, 304, 306, and 308.

In this manner, the MOS device 300 of FIG. 13 provides increased capacitance and may advantageously be used as the capacitor C in the charge pump 200 of FIG. 4. In addition, the body bias regions 322, 324, 326, 328, and 330 are formed with one continuous P well 218 for minimized area of the MOS device 300. In contrast, when multiple PMOSFETs are used for increasing capacitance in the prior art, the drain and the source of each PMOSFET are formed in separate and isolated wells such that a larger area is required for such increased capacitance in the prior art.

FIG. 16 shows the charge pump 200 being used as a cell array voltage (VBB) generator within a memory device 400 according to an embodiment of the present invention. For example, the VBB generator is implemented as the charge pump 200 for generating a voltage applied to a substrate having a memory cell array 402 formed therein. The memory device 400 is controlled by a processor device 404 that provides control signals, address signals, and data signals to the memory device 400.

The memory device 400 includes a control circuitry 406, an address circuitry 408, a voltage level translator 410, an I/O (input/output) circuitry 412, a row decoder 414, a column decoder 416, a write circuitry 418, and a read/latch circuitry 420. The processor device 404 provides respective control and address signals to the control circuitry 406 and the address circuitry 408, respectively, for a read of the memory device 400. In that case, the row and column decoders 414 and 416 and the read/latch circuitry 420 are controlled to read data from the specified address of the memory cell array 402 that provides the data therein to the processor device 404 via the I/O circuitry 412.

The processor 404 provides control, address, and data signals to the control circuitry 406, the address circuitry 408, and the I/O circuitry, respectively, for a write to the memory device 400. In that case, the row and column decoders 414 and 416 and the write circuitry 418 are controlled to write such given data to the specified address of the memory cell array 402.

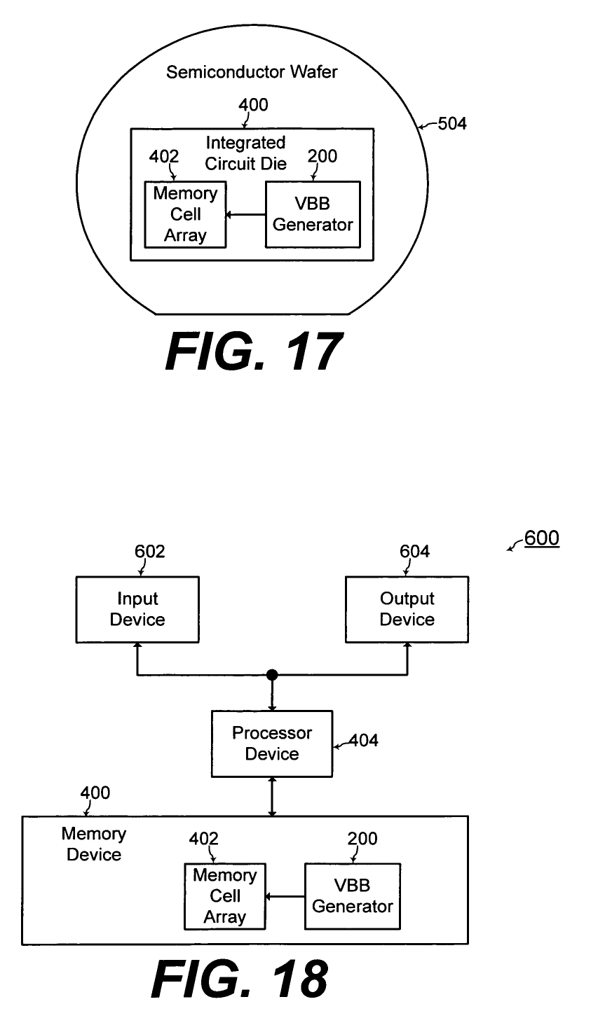

Referring to FIG. 17, the memory cell array 402 and the VBB generator 200 are part of the memory device 400 such as a flash memory device for example that is fabricated as an integrated circuit die on a semiconductor wafer 504. Referring to FIG. 18, the memory device 400 is included as part of an electronic system 600 also having the processor device 404, an input device 602, and an output device 604. The processor device 404 is coupled to and controls the input device 602, the output device 604, and the memory device 400.

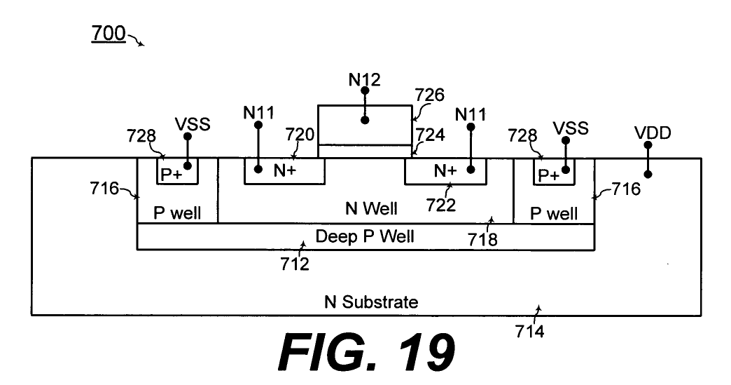

The MOS device 210 of FIG. 4 and the MOS device 300 of FIG. 13 are advantageous for generating a negative voltage at the second node N12 as the charged pumped voltage. FIG. 19 shows a cross sectional view of a MOS device 700 that may be used as the capacitor C within the charge pump 200 for generating a positive voltage at the second node N12 as the charged pumped voltage.

The MOS device 700 includes a deep well 712 formed in a semiconductor substrate 714. The MOS device 700 further includes at least one side well 716 formed to abut the deep well 712. The MOS device 700 also includes an N well 718 forming a device body of the MOS device 700.

Also in FIG. 19, the MOS device 700 includes a first body bias region 720 and a second body bias region 722 formed in the N well 718 for providing low resistance contact and biasing of the N well 718. A gate dielectric 724 is formed over a channel portion of the N well disposed between the body bias regions 720 and 722. A gate 726 is formed over the gate dielectric 724. The gate dielectric 724 is comprised of an insulating material, and the gate 726 is comprised of a conductive material.

Additionally in FIG. 19, the MOS device 700 includes a well bias region 728 formed in the side well 716 for providing low resistance contact and biasing of the side well 716 and the deep well 712. In the embodiment of FIG. 19, the deep well 712, the side well 716, and the well bias region 728 are doped to have P type conductivity. The N well forming the device body 718, the body bias regions 720 and 722, and the substrate 714 are doped to have N type conductivity.

In addition, the body bias regions 720 and 722 have a respective N type dopant concentration that is at least fifteen times higher than a respective N type dopant concentration of the N well 718. Furthermore, the well bias region 728 has a respective P type dopant concentration that is at least fifteen times higher than a respective P type dopant concentration of the side well 716 and the deep well 712. Also in FIG. 19, the body bias regions 720 and 722 form the first node N11 of the capacitor C, and the gate 726 forms the second node N12 of the capacitor C.

With such conductivities as illustrated in FIG. 19, the MOS device 700 provides stable capacitance over a wide voltage range in the charge pump 200 that generates a positive voltage at the second node N12 as the charged pumped voltage. In addition, the N well 718, the deep well 712 (with the side well 716), and the substrate 714 form a multiple-well structure of the MOS device 700. The deep well 712 and the side well 716 surround the N well 718 forming the device body of the MOS device 700. The deep well 712 and the side well 716 abut the substrate 714.

The N type substrate 714 is biased at the high power voltage VDD. In addition, the side well 716 and the deep well 712 are biased at the low power voltage VSS. Thus, the N well 718 is further electrically isolated for enhanced noise immunity of the MOS device 700.

The foregoing is by way of example only and is not intended to be limiting. For example, any number of elements as illustrated and described herein is by way of example only. The present invention is limited only as defined in the following claims and equivalents thereof.

1. A MOS (metal oxide semiconductor) capacitor, comprising:
a MOS device including at least one body bias region and a device body of a same first conductivity type and including a gate forming a first terminal of the MOS capacitor,
wherein the at least one body bias region forms a second terminal of the MOS capacitor; and
a multiple-well structure formed with the device body and a deep well in a substrate.

2. The MOS capacitor of claim 1, wherein the substrate abuts the deep well.

3. The MOS capacitor of claim 1, further comprising:
at least one side well formed to abut the deep well, wherein the side well and the deep well abut the device body; and
at least one well bias region formed in the side well,
wherein multiple body bias regions are formed to sides of the gate in the device body.

4. The MOS capacitor of claim 3, wherein the multiple body bias regions and the device body are of the first conductivity type, and wherein the at least one well bias region, the side well, and the deep well are of a second conductivity type that is opposite of the first conductivity type.

5. The MOS capacitor of claim 4, wherein the multiple body bias regions have a higher dopant concentration than the device body, and wherein the at least one well bias region has a higher dopant concentration than the side well and the deep well.

6. The MOS capacitor of claim 1, wherein the side well, the deep well, and the substrate are biased such that the substrate forms a reverse biased PN diode with the side well and the deep well.

7. The MOS capacitor of claim 1, comprising:
at least three body bias regions formed in the device body, with the body bias regions being coupled together to form the second terminal of the MOS capacitor; and
a plurality of gates, each formed over a respective portion of the device body between a respective pair of the body bias regions, with the gates being coupled together to form the first terminal of the MOS capacitor.

8. A MOS (metal oxide semiconductor) capacitor, comprising:
a depletion-type MOS device including a device body, at least one body bias region, and a gate forming a first terminal of the MOS capacitor, wherein the at least one body bias region forms a second terminal of the MOS capacitor; and
a multiple-well structure formed with the device body and a deep well in a substrate.

9. The MOS capacitor of claim 8, wherein the substrate abuts the deep well.

10. The MOS capacitor of claim 8, further comprising:
at least one side well formed to abut the deep well, wherein the side well and the deep well abut the device body; and
at least one well bias region formed in the side well,
wherein multiple body bias regions are formed to sides of the gate in the device body.

11. The MOS capacitor of claim 10, wherein the multiple body bias regions and the device body are of a first conductivity type, and wherein the at least one well bias region, the side well, and the deep well are of a second conductivity type that is opposite of the first conductivity type.

12. The MOS capacitor of claim 11, wherein the multiple body bias regions have a higher dopant concentration than the device body, and wherein the at least one well bias region has a higher dopant concentration than the side well and the deep well.

13. The MOS capacitor of claim 8, wherein the deep well, the side well, and the substrate are biased such that the substrate forms a reverse biased PN diode with the side well and the deep well.

14. The MOS capacitor of claim 8, comprising:
at least three body bias regions formed in the device body, with the body bias regions being coupled together to form the second terminal of the MOS capacitor; and
a plurality of gates, each formed over a respective portion of the device body between a respective pair of the body bias regions, with the gates being coupled together to form the first terminal of the MOS capacitor.

15. A charge pump comprising:
a MOS (metal oxide semiconductor) capacitor including:
a MOS device including at least one body bias region and a device body of a same first conductivity type and including a gate forming a first terminal of the MOS capacitor,
wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.

16. The charge pump of claim 15, wherein the substrate abuts the deep well.

17. The charge pump of claim 15, further comprising:
at least one side well formed to abut the deep well, wherein the side well and the deep well abut the device body; and
at least one well bias region formed in the side well,
wherein multiple body bias regions are formed to sides of the gate in the device body,
and wherein the multiple body bias regions and the device body are of the first conductivity type, and wherein the at least one well bias region, the side well, and the deep well are of a second conductivity type that is opposite of the first conductivity type,
and wherein the multiple body bias regions have a higher dopant concentration than the device body, and wherein the at least one well bias region has a higher dopant concentration than the side well and the deep well.

18. The charge pump of claim 15, wherein the side well, the deep well, and the substrate are biased such that the substrate forms a reverse biased PN diode with the side well and the deep well.

19. The charge pump of claim 15, wherein the at least one body bias region is doped to have a P+ conductivity, the device body is doped to have P conductivity, the deep well and the side well are doped to have N conductivity, and the substrate is doped to have P conductivity, when the pumped voltage is a negative voltage,
and wherein the at least one body bias region is doped to have a N+ conductivity, the device body is doped to have N conductivity, the side well and the deep well are doped to have P conductivity, and the substrate is doped to have N conductivity, when the pumped voltage is a positive voltage.

20. A charge pump comprising:
a MOS (metal oxide semiconductor) capacitor including:
a depletion-type MOS device including a device body, at least one body bias region, and a gate forming a first terminal of the MOS capacitor, wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.

21. The charge pump of claim 20, wherein the substrate abuts the deep well.

22. The charge pump of claim 20, further comprising:
at least one side well formed to abut the deep well, wherein the side well and the deep well abut the device body; and
at least one well bias region formed in the side well,
wherein multiple body bias regions are formed to sides of the gate in the device body,
and wherein the multiple body bias regions and the device body are of a first conductivity type, and wherein the at least one well bias region, the side well, and the deep well are of a second conductivity type that is opposite of the first conductivity type,
and wherein the multiple body bias regions have a higher dopant concentration than the device body, and wherein the at least one well bias region has a higher dopant concentration than the side well and the deep well.

23. The charge pump of claim 20, wherein the side well, the deep well, and the substrate are biased such that the substrate forms a reverse biased PN diode with the side well and the deep well.

24. The charge pump of claim 20, wherein the at least one body bias region is doped to have a P+ conductivity, the device body is doped to have P conductivity, the side well and the deep well are doped to have N conductivity, and the substrate is doped to have P conductivity, when the pumped voltage is a negative voltage,
and wherein the at least one body bias region is doped to have a N+ conductivity, the device body is doped to have N conductivity, the side well and the deep well are doped to have P conductivity, and the substrate is doped to have N conductivity, when the pumped voltage is a positive voltage.

25. A memory device comprising:
a memory cell array; and
a voltage source for generating a pumped voltage used during operation of the memory cell array, the voltage source including:
a MOS (metal oxide semiconductor) capacitor including:
a MOS device including at least one body bias region and a device body of a same conductivity type and including a gate forming a first terminal of the MOS capacitor,
wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.

26. A memory device comprising:
a memory cell array; and
a voltage source for generating a pumped voltage used during operation of the memory cell array, the voltage source including:
a MOS (metal oxide semiconductor) capacitor including:
a depletion-type MOS device including a device body, at least one body bias region, and a gate forming a first terminal of the MOS capacitor, wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.

27. An electronic system including:
an input device;
an output device;
a memory device; and
a processor device coupled to the input device, the output device, and the memory device, wherein the memory device includes:
a memory cell array; and
a voltage source for generating a pumped voltage used during operation of the memory cell array, the voltage source including:
a MOS (metal oxide semiconductor) capacitor including:
a MOS device including at least one body bias region and a device body of a same conductivity type and including a gate forming a first terminal of the MOS capacitor,
wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.

28. An electronic system including:
an input device;
an output device;
a memory device; and
a processor device coupled to the input device, the output device, and the memory device, wherein the memory device includes:
a memory cell array; and
a voltage source for generating a pumped voltage used during operation of the memory cell array, the voltage source including:
a MOS (metal oxide semiconductor) capacitor including:
a depletion-type MOS device including a device body, at least one body bias region, and a gate forming a first terminal of the MOS capacitor, wherein the at least one body bias region forms a second terminal of the MOS capacitor; and
a multiple-well structure formed with the device body and a deep well in a substrate; and
a bias source for alternately applying a voltage to at least one of the first and second terminals of the MOS capacitor for generating a pumped voltage at one of the first and second terminals of the MOS capacitor.
